(19) United States
(12) Patent Application Publication
(10) Pub. No.: US 2025/0022859 A1
(43) Pub. Date: Jan. 16, 2025

(54) SEMICONDUCTOR PACKAGE WITH GLASS CORE SUBSTRATE AND METHOD OF FABRICATING THE SAME

(71) Applicant: SAMSUNG ELECTRONICS CO., LTD., Suwon-si (KR)

(72) Inventor: Junghoon Kang, Suwon-si (KR)

(21) Appl. No.: 18/427,622

(22) Filed: Jan. 30, 2024

(30) Foreign Application Priority Data
Jul. 13, 2023 (KR) 10-2023-0091122

(51) Int. Cl. H01L 25/16; H01L 21/48; H01L 23/00; H01L 23/13; H01L 23/31; H01L 23/498; H01L 23/538; H01L 23/58; H01L 21/56

(52) U.S. Cl. CPC H01L 25/16; H01L 21/486; H01L 23/13; H01L 23/3128; H01L 23/3135; H01L 23/49827; H01L 23/49833; H01L 23/5384; H01L 23/5385; H01L 23/5389; H01L 23/58; H01L 24/19; H01L 24/20; H01L 21/568; H01L 24/16; H01L 24/32; H01L 24/73; H01L 2224/16227; H01L 2224/19; H01L 2224/211; H01L 2224/32225; H01L 2224/73204

(57) ABSTRACT

A semiconductor package includes a wiring substrate and a first semiconductor chip disposed on the wiring substrate. The wiring substrate includes a first core portion including glass and having a cavity that vertically penetrates the first core portion, first core vias that each vertically penetrate the first core portion, a passive device in the cavity of the first core portion, a buried material on the first core portion and the first core vias and filling the cavity and covering a top surface and outer lateral surfaces of the first core portion, and an upper buildup portion disposed on the buried material. The upper buildup portion includes a first dielectric pattern, and a first wiring pattern that penetrates the first dielectric pattern and the buried material and is coupled to the first core vias.

### CROSS-REFERENCE TO RELATED APPLICATION

This U.S. nonprovisional application claims priority under 35 U.S.C. § 119 to Korean Patent Application No. 10-2023-0091122, filed on Jul. 13, 2023 in the Korean Intellectual Property Office, the disclosure of which is hereby incorporated by reference in its entirety.

### TECHNICAL FIELD

The present disclosure relates to a semiconductor package, and more particularly, to a semiconductor package including a package substrate including a glass core and a method of fabricating the same.

### DISCUSSION OF THE RELATED ART

With the development of the electronic industry, electronics have become more powerful, faster, and more compact in size. To meet the trend, there has recently been developed a packaging technology in which a plurality of semiconductor chips are mounted in a single package.

A semiconductor package is a device that is used to house and protect an integrated circuit chip and to facilitate the interconnection of the chip to electronic products. Typically, a semiconductor package is configured such that a semiconductor chip is mounted on a printed circuit board (PCB) and bonding wires or bumps are used to electrically connect the packaged semiconductor chip to the printed circuit board.

### SUMMARY

Aland contact semiconductor package includes a wiring substrate and a first semiconductor chip disposed on the wiring substrate. The wiring substrate includes a first core portion including glass. The first core portion includes a cavity that vertically penetrates the first core portion. A plurality of first core vias each vertically penetrate the first core portion. A passive device is disposed in the cavity of the first core portion. A buried material is disposed on the first core portion and the first core vias. The buried material fills the cavity and covers a top surface and outer lateral surfaces of the first core portion. An upper buildup portion is disposed on the buried material. The upper buildup portion includes a first dielectric pattern and a first wiring pattern that penetrates the first dielectric pattern and the buried material and is coupled to the first core vias.

Aland contact semiconductor package includes a first interposer substrate. A second interposer substrate is disposed on the first interposer substrate. A first semiconductor chip is disposed on the second interposer substrate. A chip stack is disposed on the second interposer substrate and is spaced apart from the first semiconductor chip. The chip stack includes a plurality of second semiconductor chips that are vertically stacked. A plurality of connection terminals are disposed below the first interposer substrate. The first interposer substrate includes a lower buildup portion. A first core portion is disposed on the lower buildup portion and includes glass. the first core portion includes a cavity that vertically penetrates the first core portion. A buried material is disposed on the lower buildup portion and covers the first core portion. An upper buildup portion is disposed on the buried material. A passive device is disposed in the cavity of the first core portion. Outer lateral surfaces of the first core portion are positioned more inwardly than outer lateral surfaces of the buried material. The second interposer substrate includes a second core portion. The second core portion includes a material that is different from a material of the first core portion.

Aland contact semiconductor package includes a wiring substrate. A first semiconductor chip is disposed on the wiring substrate. The wiring substrate includes a lower buildup portion. An upper buildup portion is disposed on the lower buildup portion. A buried material fills a space between the lower buildup portion and the upper buildup portion. A first core portion is disposed in the buried material. The first core portion includes a cavity that penetrates the first core portion. A distance between outer lateral surfaces of the first core portion and outer lateral surfaces of the buried material is in a range of about 0.1 mm to about 3 mm. A plurality of first core vias each vertically penetrate the first core portion. A passive device is disposed in the cavity of the first core portion. The upper buildup portion includes a first dielectric pattern and a first wiring pattern that penetrates the first dielectric pattern and the buried material and is coupled to the first core vias. The lower buildup portion includes a second dielectric pattern. A second wiring pattern penetrates the second dielectric pattern and is coupled to the first core vias. A stiffness of a first material included in the first core portion is greater than a stiffness of a second material included in the first dielectric pattern and a stiffness of a third material included in the second dielectric pattern.

Aland contact method of fabricating a semiconductor package includes providing, on a carrier substrate, a core portion including glass. An etching process is performed on the core portion to form a plurality of cavities, a plurality of via holes, and a plurality of trenches. The cavities, the via holes, and the trenches vertically penetrate the core portion. The trenches define a plurality of substrate regions that are spaced apart from each other. The cavities and the via holes are disposed in the substrate regions. A conductive material fills the via holes to form a plurality of core vias. A plurality of passive devices are placed in the cavities. A buried material is formed that fills the cavities and the trenches and covers the core portion and the core vias. The carrier substrate is removed to expose a bottom surface of the buried material, a bottom surface of the core portion, and bottom surfaces of the passive devices. A lower buildup portion is formed on the bottom surface of the buried material and the bottom surface of the core portion. The lower buildup portion is electrically connected to the core vias. An upper buildup portion is formed on the buried material. A wiring pattern of the upper buildup portion penetrates the buried material and is electrically connected to the core vias. A cutting process is performed on the buried material, the upper buildup portion, and the lower buildup portion to separate a plurality of wiring substrates from each other. The cutting process is performed along the trenches. A semiconductor chip is mounted on the wiring substrate. A cutting surface of the cutting process is horizontally spaced apart from the core portion.

### BRIEF DESCRIPTION OF DRAWINGS

FIG. 1 is a cross-sectional view of a semiconductor package according to embodiments of the present inventive concepts.

FIG. 2 is an enlarged view of section A of FIG. 1.

FIG. 3 is a plan view of a semiconductor package according to embodiments of the present inventive concepts.

FIG. 4 is a cross-sectional view of a semiconductor package according to embodiments of the present inventive concepts.

FIG. 5 is an enlarged view of section B of FIG. 4.

FIGS. 6 and 7 are cross-sectional views of a semiconductor package according to embodiments of the present inventive concepts.

FIG. 8 is an enlarged view of section C of FIG. 7.

FIG. 9 is a cross-sectional view of a semiconductor package according to embodiments of the present inventive concepts.

FIG. 10 is an enlarged view of section D of FIG. 9.

FIGS. 11 and 12 are cross-sectional views of a semiconductor package according to embodiments of the present inventive concepts.

FIGS. 13A to 19A are cross-sectional views of a method of fabricating a semiconductor package according to embodiments of the present inventive concepts.

FIGS. 13B to 19B are plan views of a method of fabricating a semiconductor package according to embodiments of the present inventive concepts.

### DETAILED DESCRIPTION OF EMBODIMENTS

The following will now describe a semiconductor package according to the present inventive concepts with reference to the accompanying drawings.

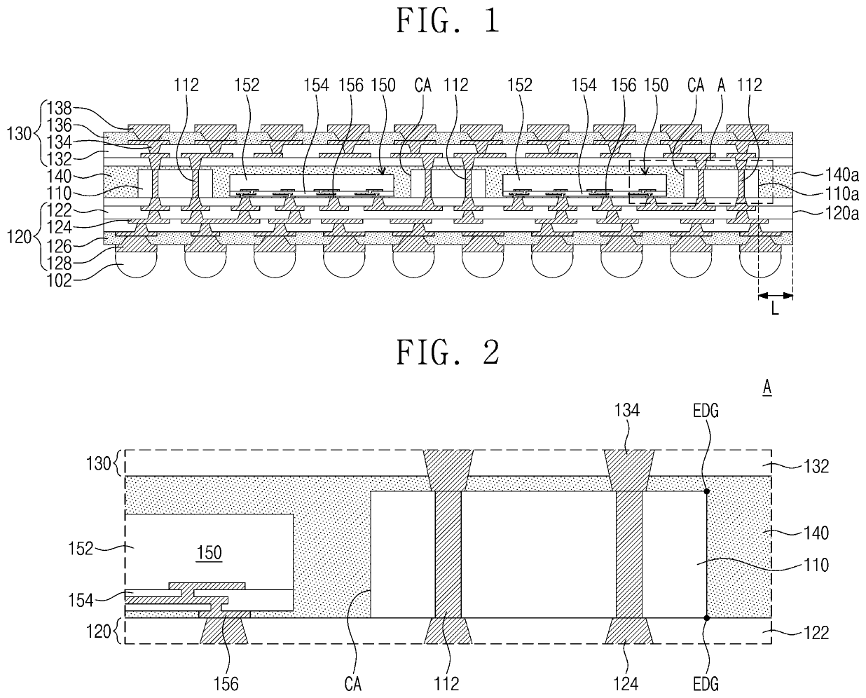

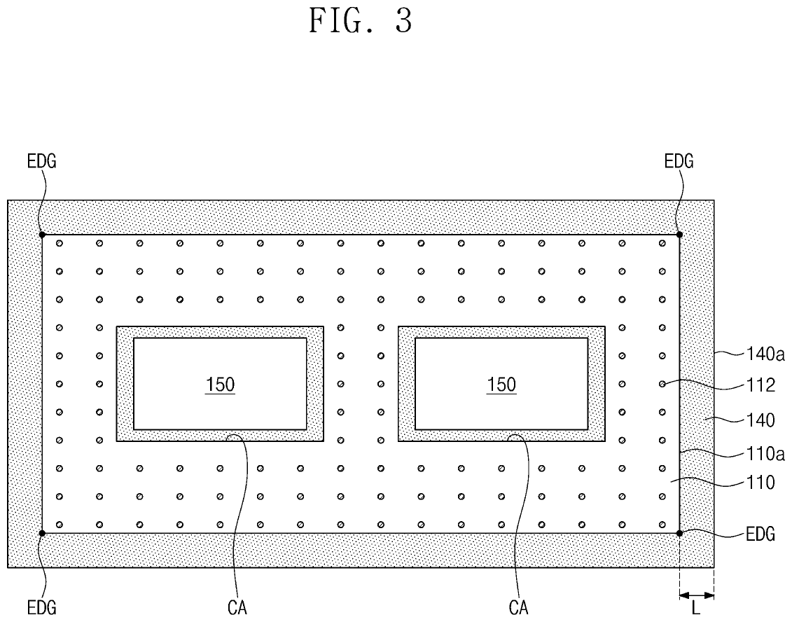

FIG. 1 is a cross-sectional view of a semiconductor package according to embodiments of the present inventive concepts. FIG. 2 is an enlarged view of section A of FIG. 1. FIG. 3 is a plan view of a semiconductor package according to embodiments of the present inventive concepts.

Referring to FIGS. 1 to 3, a semiconductor package may include a semiconductor chip and a package substrate for mounting the chip to an external apparatus or an external substrate.

A package substrate may be provided. The package substrate may include a core portion 110, a lower buildup portion 120 disposed on a bottom surface of the core portion 110, an upper buildup portion 130 disposed on a top surface of the core portion 110, and a buried material 140.

The lower buildup portion 120 may cover the bottom surface of the core portion 110. The lower buildup portion 120 may include one or more first substrate wiring layers sequentially stacked on the bottom surface of the core portion 110. For example, the lower buildup portion 120 may include three first substrate wiring layers. Each of the first substrate wiring layer may include a lower dielectric pattern 122 and a lower wiring pattern 124 in the lower dielectric pattern 122. The lower wiring pattern 124 of a certain first substrate wiring layer may be electrically connected to the lower wiring pattern 124 of another first substrate wiring layer adjacent to the certain first substrate wiring layer.

A material included in the lower dielectric pattern 122 may have a stiffness that is less than that of a material included in the core portion 110. The lower dielectric pattern 122 may include a dielectric polymer or a photo-imageable dielectric (PID). Alternatively, the lower dielectric pattern 122 may include a prepreg, an ajinomoto buildup film (ABF), a flame retardant 4 (FR-4), or bismaleimide triazine (BT).

The lower wiring patterns 124 may include a circuit pattern. The lower wiring pattern 124 may be disposed on the lower dielectric pattern 122. The lower wiring pattern 124 may be disposed on a bottom surface of the lower dielectric pattern 122. The lower wiring pattern 124 may protrude onto the bottom surface of the lower dielectric pattern 122. The lower wiring pattern 124 may extend horizontally on the bottom surface of the lower dielectric pattern 122. Below the lower dielectric pattern 122, the lower wiring pattern 124 may be covered with another lower dielectric pattern 122. The lower wiring pattern 124 may be a pad or line part of the first substrate wiring layer. The lower wiring pattern 124 may include an electrically conductive material. For example, the lower wiring pattern 124 may include copper (Cu), aluminum (Al), silver (Ag), tin (Sn), gold (Au), nickel (Ni), lead (Pb), titanium (Ti), and any combination thereof.

The lower wiring pattern 124 may have a damascene structure. For example, the lower wiring pattern 124 may have a via that protrudes onto a top surface thereof. The via may be a component for vertical connection between the lower wiring patterns 124 of neighboring first substrate wiring layers. For example, the via may extend from the top surface of the lower wiring pattern 124 through the lower dielectric pattern 122 and may be coupled to a bottom surface of the lower wiring pattern 124 in overlying another first substrate wiring layer. A lower portion of the lower wiring pattern 124 disposed below the lower dielectric pattern 122 may be a head part used as a horizontal wiring line or pad, and the via of the lower wiring pattern 124 may be a tail part. The lower wiring pattern 124 may have an inverse T shape.

A lower substrate protection layer 126 may be disposed below the lower buildup portion 120. The lower substrate protection layer 126 may cover a lowermost first substrate wiring layer. On a bottom surface of the lowermost first substrate wiring layer, the lower substrate protection layer 126 may cover the lower wiring pattern 124. The lower substrate protection layer 126 may include a prepreg, an ajinomoto buildup film (ABF), a flame retardant 4 (FR-4), or bismaleimide triazine (BT). The lower substrate protection layer 126 might not be provided, if necessary.

Lower substrate pads 128 may be disposed on a bottom surface of the lower substrate protection layer 126. The lower substrate pads 128 may vertically penetrate the lower substrate protection layer 126 and may be coupled to the lower wiring pattern 124 of the lowermost first substrate wiring layer.

According to embodiments, the lower substrate protection layer 126 may cover the bottom surface of the lowermost first substrate wiring layer, and may expose the bottom surface of the lower wiring pattern 124 exposed on the bottom surface of the lowermost first substrate wiring layer. In this case, the exposed lower wiring pattern 124 may serve as substrate pads. The following description will focus on the embodiment of FIG. 1.

External terminals 102 may be disposed on bottom surfaces of the lower substrate pads 128. The external terminals 102 may include solder balls or solder bumps. Based on type and arrangement of the external terminals 102, the semiconductor package may be disposed in the form of a ball grid array (BGA) type, a fine ball-grid array (FBGA) type, or a land grid array (LGA) type.

The core portion 110 may be disposed on the lower buildup portion 120. The core portion 110 may extend in one direction. In a plan view, the core portion 110 may include a single core pattern. For example, the core portion 110 may have a plate shape. Although the core portion 110 having a single core pattern is discussed by way of example, the present inventive concepts are not necessarily limited thereto. According to embodiments, the core portion 110 may include two or more core patterns. For example, the package substrate may include a plurality of core patterns that are spaced apart from each other in a plan view. The core portion 110 may be in contact with a top surface of the lower buildup portion 120. The core portion 110 may have a width that is less than that of the lower buildup portion 120. For example, the core portion 110 may have a planar shape that is smaller than that of the lower buildup portion 120. In a plan view, the core portion 110 may be disposed inside the lower buildup portion 120. For example, the core portion 110 may have outer lateral surfaces 110a that are spaced apart in an inward direction from outer lateral surfaces 120a of the lower buildup portion 120. A material included in the core portion 110 may have a stiffness that is greater than that of a material included in the lower dielectric pattern 122 and that of a material included in an upper dielectric pattern 132 which will be discussed below. The core portion 110 may include a dielectric material. For example, the core portion 110 may include a glass fiber. For example, the package substrate may be glass-based wiring substrate.

The core portion 110 may include one or more cavities CA that penetrate therethrough. For example, the cavities CA may be shaped like an open hole that connects the top and bottom surfaces of the core portion 110. The cavities CA may be defined to indicate spaces in which are provided inner devices 150 which will be discussed below. In a plan view, each of the cavities CA may be disposed adjacent to a central section of the core portion 110.

The core portion 110 may include vertical connection terminals 112 that each vertically penetrate the core portion 110. The vertical connection terminals 112 may extend from the bottom surface of the core portion 110 toward the top surface of the core portion 110. For example, the vertical connection terminals 112 may be core vias for a vertical electrical connection in the core portion 110. The vertical connection terminals 112 may be exposed on the bottom surface of the core portion 110 and the top surface of the core portion 110. The vertical connection terminals 112 may have bottom surfaces that are coplanar with the bottom surface of the core portion 110. The vertical connection terminals 112 may have top surfaces that are coplanar with the top surface of the core portion 110. In a plan view, the vertical connection terminals 112 may be disposed outside the cavities CA. For example, the vertical connection terminals 112 may be disposed between the cavities CA and the outer lateral surfaces 110a of the core portion 110. In addition, in a plan view, the vertical connection terminals 112 may be disposed between the cavities CA. The vertical connection terminals 112 may electrically connect the upper buildup portion 130 to the lower buildup portion 120. The lower wiring pattern 124 of an uppermost first substrate wiring layer in the lower buildup portion 120 may penetrate the lower dielectric pattern 122 and may be coupled to the vertical connection terminals 112. The vertical connection terminals 112 may thus be electrically connected to the lower buildup portion 120. The vertical connection terminals 112 may include a metal, such as copper (Cu) or tungsten (W).

One or more inner devices 150 may be disposed on the lower buildup portion 120. The inner devices 150 may be correspondingly disposed in the cavities CA of the core portion 110. FIG. 1 depicts that one inner device 150 is disposed in one cavity CA, but the present inventive concepts are not necessarily limited thereto. According to embodiments, two or more inner devices 150 may be disposed in one cavity CA. The inner devices 150 may be disposed on the lower buildup portion 120 exposed by the cavities CA. The inner devices 150 may be in contact with the top surface of the lower buildup portion 120. The inner devices 150 may be spaced apart from the core portion 110. For example, the inner devices 150 may be correspondingly spaced apart from inner sidewalls of the cavities CA. The inner devices 150 may have top surfaces located at a level, from the lower buildup portion 120, that is the same as or lower than that of the top surface of the core portion 110. The inner devices 150 may be passive devices. For example, the inner devices 150 may include a resistor, a capacitor, or an inductor. According to embodiment, the inner devices 150 may be a memory chip or a logic chip.

The inner devices 150 may be electrically connected to the lower buildup portion 120. A direct bonding may be employed to mount the inner devices 150 on the lower buildup portion 120. For example, each of the inner devices 150 may include a semiconductor layer 152 having the passive devices on a bottom surface thereof, a device wiring layer 154 disposed on the bottom surface of the semiconductor layer 152 and electrically connected to the passive devices, and chip pads 156 disposed on a bottom surface of the device wiring layer 154 and electrically connected through the device wiring layer 154 to the passive devices. The chip pads 156 may be disposed on bottom surfaces of the inner devices 150. For example, the bottom surfaces of the inner devices 150 may be active surfaces. The inner devices 150 may be disposed in a face-down state on the lower buildup portion 120. The chip pads 156 may protrude from the bottom surface of the device wiring layer 154. The inner devices 150 may be in contact with the lower buildup portion 120. The chip pads 156 may vertically separate the device wiring layer 154 from the lower buildup portion 120. For example, the chip pads 156 of the inner devices 150 may be in contact with the top surface of the lower buildup portion 120, and between the chip pads 156, an empty space may be disposed between the lower buildup portion 120 and the device wiring layer 154 of the inner devices 150. The lower wiring pattern 124 of the first substrate wiring layer in the lower buildup portion 120 may penetrate an uppermost lower dielectric pattern 122 and may be coupled to the chip pads 156 of the inner devices 150. Therefore, the inner devices 150 may be electrically connected to the lower buildup portion 120.

The buried material 140 may be disposed on the lower buildup portion 120. On the lower buildup portion 120, the buried material 140 may cover the core portion 110. On the lower buildup portion 120, the buried material 140 may completely bury the core portion 110. For example, the buried material 140 may cover the top surface and the outer lateral surfaces 110a of the core portion 110. The buried material 140 may have outer lateral surfaces 140a that are spaced apart from the outer lateral surfaces 110a of the core portion 110. For example, the outer lateral surfaces 110a of the core portion 110 may be positioned more inwardly than the outer lateral surfaces 140a of the buried material 140. A length L of about 0.1 mm to about 3 mm may be disposed between the outer lateral surfaces 110a of the core portion 110 and the outer lateral surfaces 140a of the buried material 140. The buried material 140 may cover the top surface of the core portion 110, and neither the core portion 110 nor the vertical connection terminals 112 may be exposed by the buried material 140. The buried material 140 may fill the cavities CA. For example, in the cavities CA, the buried material 140 may cover the inner devices 150. The buried material 140 may fill a space between the inner devices 150 and inner walls of the cavities CA, and a space between the inner devices 150 and the lower buildup portion 120. For example, the buried material 140 may fill unoccupied portions of the cavities CA in which the inner devices 150 are disposed. A bottom surface of the buried material 140 may be coplanar with that of the core portion 110. The buried material 140 may have a width that is substantially the same as that of the lower buildup portion 120. For example, the outer lateral surfaces 140a of the buried material 140 may be vertically aligned with the outer lateral surfaces 120a of the lower buildup portion 120. The outer lateral surfaces 140a of the buried material 140 may be substantially coplanar with the outer lateral surfaces 120a of the lower buildup portion 120. The buried material 140 may include a dielectric material. For example, the buried material 140 may include an ajinomoto buildup film (ABF) or an epoxy molding compound (EMC).

According to embodiments of the present inventive concepts, the core portion 110 may contact the top surface of the lower buildup portion 120, and on the lower buildup portion 120, the buried material 140 may bury the core portion 110. Therefore, the buried material 140 may be in contact with all of edges EDG of the core portion 110. Therefore, the buried material 140 may protect the edges EDG of the core portion 110. When the core portion 110 is formed of glass, the edges EDG may be more fragile than any other portions (e.g., surface or inside). According to the present inventive concepts, the buried material 140 may protect the core portion 110, in particular the edges EDG of the core portion 110, against external impact and/or stress, and it may be possible to provide a package substrate whose structural stability is increased and a semiconductor package including the package substrate.

The upper buildup portion 130 may be disposed on a top surface of the buried material 140. The upper buildup portion 130 may cover the top surface of the buried material 140. The upper buildup portion 130 may include one or more second substrate wiring layers that are sequentially stacked on the top surface of the buried material 140. For example, the upper buildup portion 130 may include two “second substrate wiring layers”. Each of the second substrate wiring layers may include an upper dielectric pattern 132 and an upper wiring pattern 134 in the upper dielectric pattern 132. The upper dielectric pattern 132 of a certain second substrate wiring layer may be electrically connected to the upper dielectric pattern 132 of another second substrate wiring layer adjacent to the certain second substrate wiring layer.

A material included in the upper dielectric pattern 132 may have a stiffness that is less than that of a material included in the core portion 110. The upper dielectric pattern 132 may include a dielectric polymer or a photo-imageable dielectric (PID). Alternatively, the upper dielectric pattern 132 may include a prepreg, an ajinomoto buildup film (ABF), a flame retardant 4 (FR-4), or bismaleimide triazine (BT).

The upper wiring pattern 134 may include a circuit pattern. The upper wiring pattern 134 may be disposed on the upper dielectric pattern 132. The upper wiring pattern 134 may be disposed on a top surface of the upper dielectric pattern 132. The upper wiring pattern 134 may protrude onto the top surface of the upper dielectric pattern 132. The upper wiring pattern 134 may extend horizontally on the top surface of the upper dielectric pattern 132. On the upper dielectric pattern 132, the upper wiring pattern 134 may be covered with another upper dielectric pattern 132. The upper wiring pattern 134 may be a pad or line part of the second substrate wiring layer. The upper wiring pattern 134 may include a conductive material. For example, the upper wiring pattern 134 may include copper (Cu), aluminum (Al), silver (Ag), tin (Sn), gold (Au), nickel (Ni), lead (Pb), titanium (Ti), and any combination thereof.

The upper wiring pattern 134 may have a damascene structure. For example, the upper wiring pattern 134 may have a via that protrudes onto a bottom surface thereof. The via may be a component for vertical connection between the upper wiring patterns 134 of neighboring second substrate wiring layers. For example, the via may extend from the bottom surface of the upper wiring pattern 134 through the upper dielectric pattern 132 and is coupled to a top surface of the upper wiring pattern 134 in underlying another second substrate wiring layer. An upper portion of the upper wiring pattern 134 positioned on the upper dielectric pattern 132 may be a head part used as a horizontal wiring line or pad, and the via of the upper wiring pattern 134 may be a tail part. The upper wiring pattern 134 may have a T shape.

The upper buildup portion 130 may be electrically connected to the vertical connection terminals 112. The upper wiring pattern 134 of a lowermost second substrate wiring layer in the upper buildup portion 130 may penetrate the upper dielectric pattern 132 and the buried material 140 and may be coupled to the vertical connection terminals 112. Therefore, the upper buildup portion 130 may be electrically connected through the vertical connection terminals 112 to the lower buildup portion 120.

An upper substrate protection layer 136 may be disposed on the upper buildup portion 130. The upper substrate protection layer 136 may cover an uppermost second substrate wiring layer. On a top surface of the uppermost second substrate wiring layer, the upper substrate protection layer 136 may cover the upper wiring pattern 134. The upper substrate protection layer 136 may include a prepreg, an ajinomoto buildup film (ABF), a flame retardant 4 (FR-4), or bismaleimide triazine (BT). The upper substrate protection layer 136 might not be provided, if necessary.

Upper substrate pads 138 may be disposed on a top surface of the upper substrate protection layer 136. The upper substrate pads 138 may vertically penetrate the upper substrate protection layer 136 and may be coupled to the upper wiring pattern 134 of the uppermost second substrate wiring layer.

According to embodiments, the upper substrate protection layer 136 may cover the top surface of the uppermost second substrate wiring layer, and may expose the top surface of the upper wiring pattern 134 exposed on the top surface of the uppermost second substrate wiring layer. In this case, the exposed upper wiring pattern 134 may serve as substrate pads.

In the embodiments that follow, components the same as those discussed with reference to FIGS. 1 to 3 may be allocated the same reference numerals thereto, and to the extent that an element is not described in detail with respect to this figure, it may be understood that the element is at least similar to a corresponding element that has been described elsewhere within the present disclosure. The following description will focus on a difference between the embodiments of FIGS. 1 to 3 and other embodiments described below.

FIGS. 1 to 3 depict that the vertical connection terminals 112 are disposed in the core portion 110. For example, it is illustrated that the top surfaces of the vertical connection terminals 112 are coplanar with the top surface of the core portion 110, and the bottom surfaces of the vertical connection terminals 112 are coplanar with the bottom surface of the core portion 110. The present inventive concepts, however, are not necessarily limited thereto.

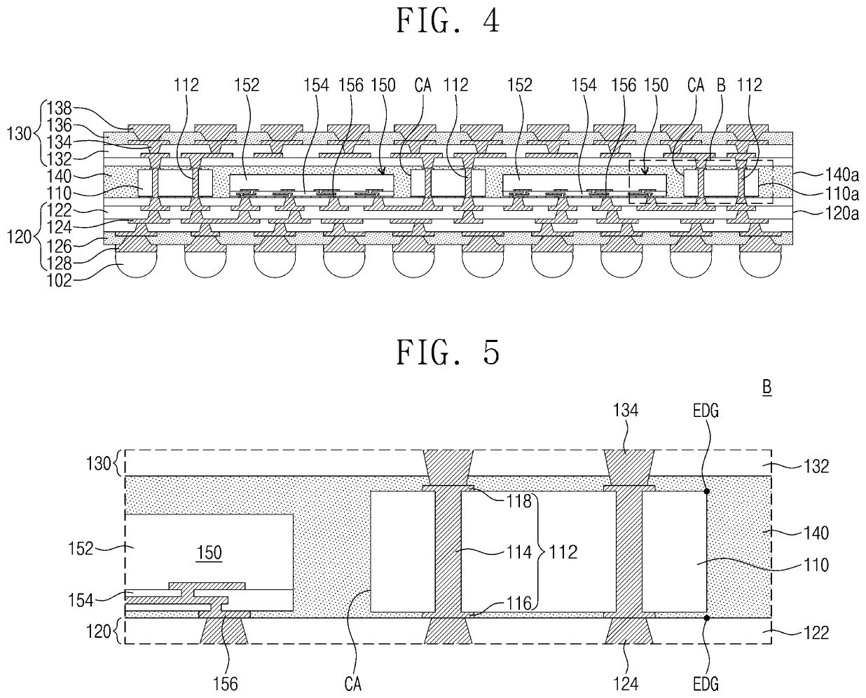

FIG. 4 is a cross-sectional view of a semiconductor package according to embodiments of the present inventive concepts. FIG. 5 illustrates an enlarged view showing section B of FIG. 4.

Referring to FIGS. 4 and 5, a portion of each of the vertical connection terminals 112 may extend onto the top surface of the core portion 110 or the bottom surface of the core portion 110. The following will describe one vertical connection terminal 112.

The vertical connection terminal 112 may include a via 114 that vertically penetrates the core portion 110. The via 114 may be a portion of the vertical connection terminal 112 positioned in the core portion 110.

A portion of the vertical connection terminal 112 may extend onto the bottom surface of the core portion 110. The portion of the vertical connection terminal 112 that protrudes onto the bottom surface of the core portion 110 may correspond to a first land contact 116 that is a pad for coupling the lower buildup portion 120 to the lower buildup portion 120. For example, the lower wiring pattern 124 of the uppermost first substrate wiring layer in the lower buildup portion 120 may penetrate the lower dielectric pattern 122 and may be coupled to the first land contact 116. The first land contact 116 may separate the core portion 110 from the lower buildup portion 120. For example, an interval between the bottom surface of the core portion 110 and the top surface of the lower buildup portion 120 may correspond to a thickness of the first land contact 116. A space between the core portion 110 and the lower buildup portion 120 may be filled with the buried material 140. The buried material 140 may at least partially surround the first land contact 116 between the core portion 110 and the lower buildup portion 120.

According to embodiments of the present inventive concepts, the buried material 140 may cover all of the top surface, the outer lateral surface 120a, and the bottom surface of the core portion 110. The buried material 140 may be in contact with all of the edges EDG of the core portion 110. For example, the core portion 110 may be completely buried in the buried material 140, and the buried material 140 may protect the edges EDG of the core portion 110 against external impact and stress, and there may be provided a package substrate whose structural stability is increased and a semiconductor package including the package substrate having the increased structural stability.

Another portion of the vertical connection terminal 112 may extend onto the top surface of the core portion 110. This other portion of the vertical connection terminal 112 that protrudes onto the top surface of the core portion 110 may correspond to a second land contact 118 that is a pad to which the upper buildup portion 130 is coupled. For example, the upper wiring pattern 134 of the lowermost second substrate wiring layer in the upper buildup portion 130 may penetrate the upper dielectric pattern 132 and the buried material 140 and may be coupled to the vertical connection terminals 112. The buried material 140 may cover the second land contact 118 and the top surface of the core portion 110.

FIGS. 4 and 5 depict that the first land contact 116, the second land contact 118, and the via 114 are provided as a single unitary body, but the present inventive concepts are not necessarily limited thereto. According to embodiments, the first land contact 116 and the second land contact 118 may be provided as a discrete component from the via 114. For example, the first land contact 116 may be disposed on the bottom surface of the core portion 110, and the second land contact 118 may be disposed on the top surface of the core portion 110. The via 114 may vertically penetrate the core portion 110 and may connect the first land contact 116 and the second land contact 118 to each other.

According to embodiments, a protection pattern may be disposed on one or both of the top and bottom surfaces of the core portion 110. The protection pattern may at least partially surround the first land contact 116 or the second land contact 118. The first land contact 116 or the second land contact 118 may be exposed on one surface of the protection pattern. The one surface of the protection pattern may be coplanar with a top surface of the first land contact 116 or a bottom surface of the second land contact 118. In this case, the protection pattern that at least partially surrounds the second land contact 118 may be in contact with the lower buildup portion 120. For example, a space between the core portion 110 and the lower buildup portion 120 may be filled with the protection pattern.

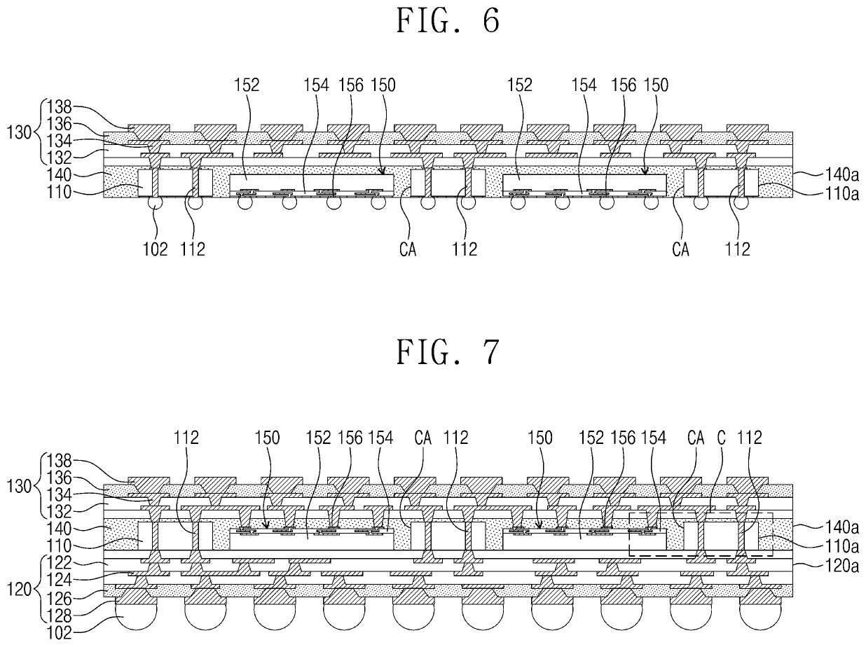

FIG. 6 is a cross-sectional view of a semiconductor package according to embodiments of the present inventive concepts.

Referring to FIG. 6, the lower buildup portion 120 might not be disposed on the package substrate in a semiconductor package. For example, the bottom surface of the buried material 140 may be exposed, the bottom surfaces of the inner devices 150 may be exposed, and the bottom surface of the core portion 110 may be exposed. The buried material 140 may cover the bottom surface of the device wiring layer 154 included in the inner devices 150, and the chip pads 156 may be exposed on the bottom surface of the buried material 140. When the vertical connection terminals 112 include the first land contacts 116 and the second land contacts 118 as in the embodiment of FIGS. 4 and 5, the buried material 140 may cover the bottom surface of the core portion 110, and the first land contacts 116 may be exposed on the bottom surface of the buried material 140. For example, the chip pads 156 and the first land contacts 116 may be exposed on the bottom surface of the buried material 140.

The external terminals 102 may be disposed below the core portion 110 and the inner devices 150. The external terminals 102 may be coupled to bottom surfaces of the chip pads 156 and bottom surfaces of the vertical connection terminals 112 (or bottom surfaces of the first land contacts 116).

According to embodiments, as the core portion 110 is buried in the buried material 140, even when the lower buildup portion 120 is not disposed below the core portion 110, edges of the core portion 110 may be protected by the buried material 140. In addition, as the lower buildup portion 120 is not provided, the package substrate may have a reduced thickness. Accordingly, there may be provided a package substrate whose structural stability is increased and whose size is decreased, and may also be a semiconductor package including the package substrate.

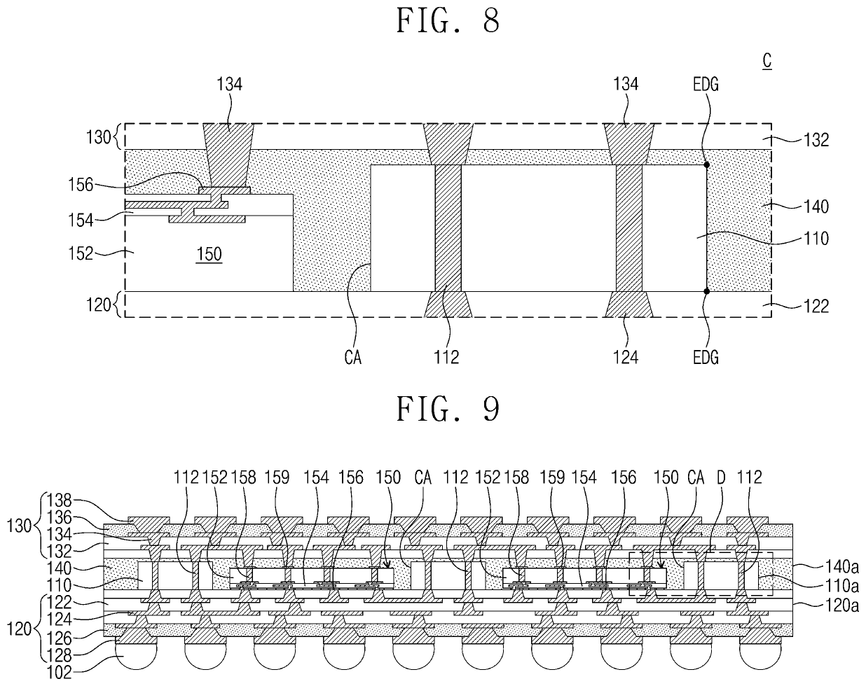

FIG. 7 is a cross-sectional view of a semiconductor package according to embodiments of the present inventive concepts. FIG. 8 is an enlarged view of section C of FIG. 7.

FIGS. 1 to 6 depict that the inner devices 150 are disposed in a face-down state on the lower buildup portion 120, but the present inventive concepts are not necessarily limited thereto.

Referring to FIGS. 7 and 8, the inner devices 150 may be disposed in a face-up state on the lower buildup portion 120. For example, each of the inner devices 150 may include a semiconductor layer 152 having passive devices on a top surface thereof, a device wiring layer 154 disposed on the top surface of the semiconductor layer 152 and electrically connected to the passive devices, and chip pads 156 disposed on a top surface of the device wiring layer 154 and electrically connected through the device wiring layer 154 to the passive devices. The chip pads 156 may be disposed on top surfaces of the inner devices 150. For example, the top surfaces of the inner devices 150 may be active surfaces. The inner devices 150 may have inactive surfaces, or bottom surfaces, in contact with the lower buildup portion 120. If necessary, an adhesion layer may be disposed on the bottom surfaces of the inner devices 150.

As the inactive surfaces of the inner devices 150 are in contact with the lower buildup portion 120, the inner devices 150 might not be directly electrically connected to the lower buildup portion 120. For example, the inner devices 150 may be electrically connected to the lower buildup portion 120 through the upper buildup portion 130 and the core portion 110.

The inner devices 150 may be electrically connected to the upper buildup portion 130. For example, the upper wiring pattern 134 of the lowermost second substrate wiring layer in the upper buildup portion 130 may penetrate the upper dielectric pattern 132 and the buried material 140 and may be coupled to the chip pads 156.

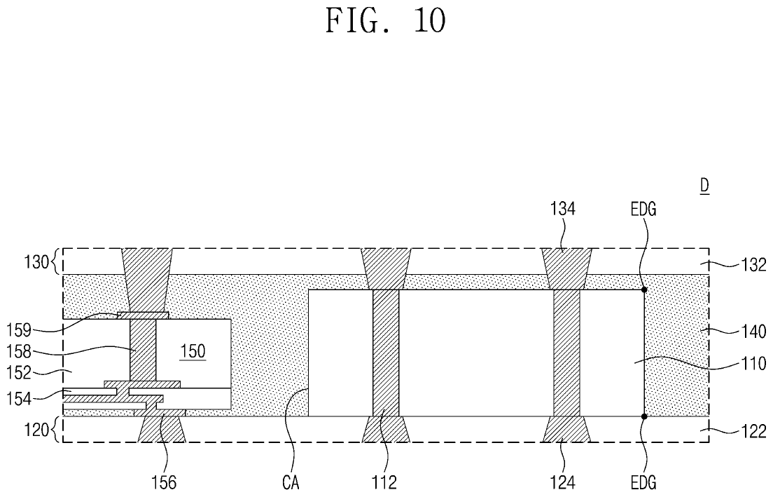

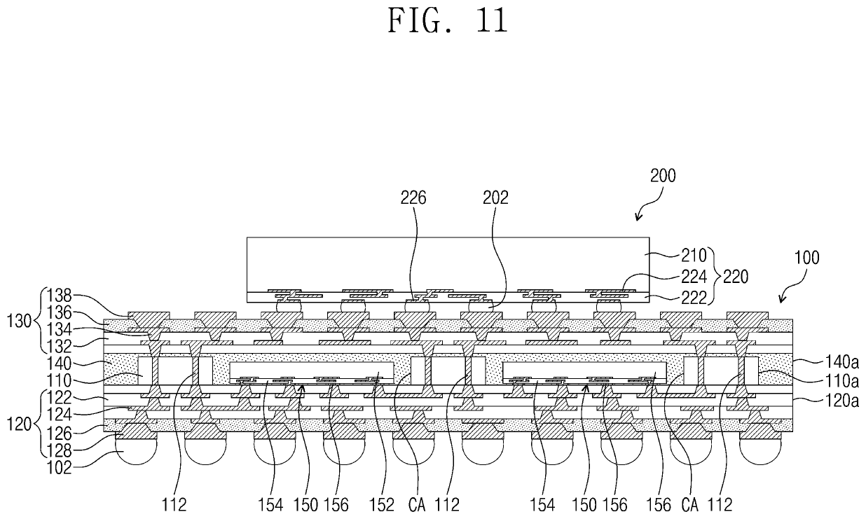

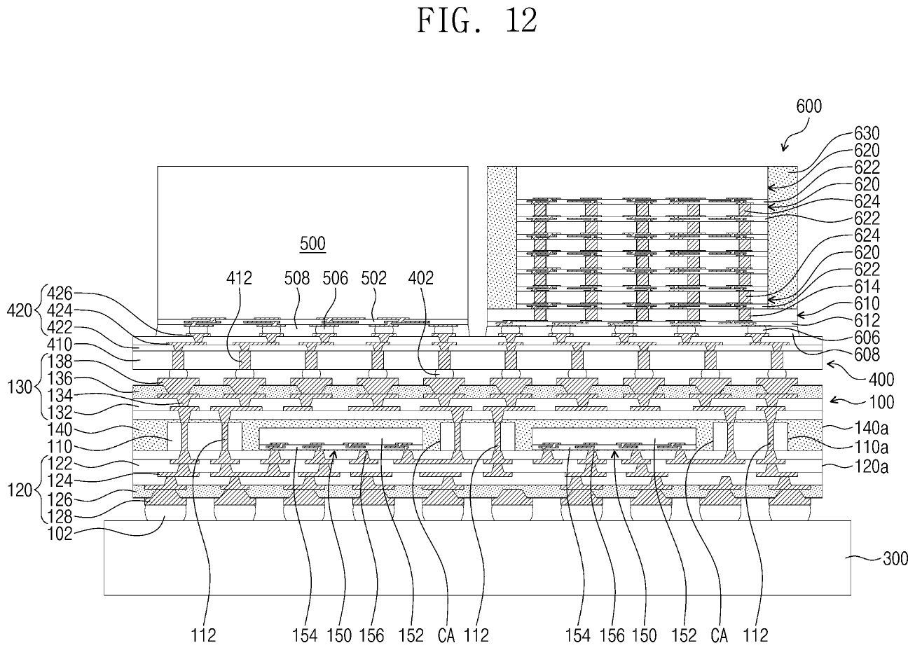

FIG. 9 is a cross-sectional view of a semiconductor package according to embodiments of the present inventive concepts. FIG. 10 is an enlarged view of section D of FIG. 9.

Referring to FIGS. 9 and 10, each of the inner devices 150 may include chip vias 158 and chip backside pads 159.

The chip vias 158 may vertically penetrate the semiconductor layer 152 and may be electrically connected to the device wiring layer 154. The chip vias 158 may be exposed on inactive surfaces, or top surfaces, of the inner devices 150. The chip vias 158 may include a conductive material. For example, the chip vias 158 may include a metal, such as copper (Cu) or tungsten (W).

The chip backside pads 159 may be disposed on a top surface of the semiconductor layer 152. On the top surface of the semiconductor layer 152, each of the chip backside pads 159 may be electrically connected to one of the chip vias 158. The chip backside pads 159 may include an electrically conductive material. For example, the chip backside pads 159 may include a metal, such as copper (Cu) or tungsten (W).

A backside protection layer may be disposed on the top surface of the semiconductor layer 152. The backside protection layer may cover the top surface of the semiconductor layer 152. The backside protection layer may at least partially surround the chip backside pads 159. A top surface of the backside protection layer may be substantially flat and coplanar with those of the chip backside pads 159. The backside protection layer may include a dielectric material. For example, the backside protection layer may include silicon oxide (SiO), silicon nitride (SiN), or silicon oxynitride (SiON). The backside protection layer might not be provided, if necessary.

FIG. 11 is a cross-sectional view of a semiconductor package according to embodiments of the present inventive concepts.

Referring to FIG. 11, a semiconductor package may further include a package substrate 100 and a first semiconductor chip 200.

The package substrate 100 may be the same as or similar to the package substrate discussed with reference to FIGS. 1 to 10. For example, the package substrate 100 may include a core portion 110, a lower buildup portion 120, an upper buildup portion 130, and a buried material 140. The buried material 140 may bury the core portion 110 between the lower buildup portion 120 and the upper buildup portion 130, and the inner devices 150 may be inserted into the cavity CA formed in the core portion 110.

The first semiconductor chip 200 may be disposed on the package substrate 100. The first semiconductor chip 200 may include a first chip base layer 210 and a first chip wiring layer 220.

The first chip base layer 210 may include a semiconductor substrate. For example, the first chip base layer 210 may be a semiconductor substrate such as a semiconductor wafer. A first integrated circuit may be disposed on a bottom surface of the first chip base layer 210. The first integrated circuit may include a logic circuit or a memory circuit. For example, the first semiconductor chip 200 may be a logic chip or a memory chip. A bottom surface of the first semiconductor chip 200 may be an active surface, and a top surface of the first semiconductor chip 200 may be an inactive surface. For example, the first semiconductor chip 200 may be disposed in a face-down state on the package substrate 100.

The first chip wiring layer 220 may be disposed on the bottom surface of the first chip base layer 210. For example, the first chip wiring layer 220 may include a first chip dielectric pattern 222 and a first chip wiring pattern 224 formed on the bottom surface of the first chip base layer 210. The first chip base layer 210 may further include a circuit pattern or a protection layer, if necessary.

On the bottom surface of the first chip base layer 210, the first chip dielectric pattern 222 may cover the first integrated circuit. The first chip dielectric pattern 222 may include a dielectric material.

The first chip wiring pattern 224 may be disposed in the first chip dielectric pattern 222. The first chip wiring pattern 224 may be electrically connected to the first integrated circuit formed on a bottom surface of the first chip dielectric pattern 222. The first chip wiring pattern 224 may include a conductive material. A portion of the first chip wiring pattern 224 exposed on the bottom surface of the first chip base layer 210 may be chip pads 226 of the first semiconductor chip 200.

The first semiconductor chip 200 may be disposed on the package substrate 100. For example, the first semiconductor chip 200 may be flip-chip mounted on the package substrate 100. The first semiconductor chip 200 may be electrically connected to the package substrate 100 through first connection terminals 202. The first connection terminals 202 may be disposed between the chip pads 226 of the first semiconductor chip 200 and the upper substrate pads 138 of the package substrate 100. The first semiconductor chip 200 may be electrically connected through the first connection terminals 202 to the inner devices 150 and to the upper buildup portion 130, the core portion 110, and the lower buildup portion 120 of the package substrate 100.

FIG. 12 is a cross-sectional view of a semiconductor package according to embodiments of the present inventive concepts.

Referring to FIG. 12, a semiconductor package may be a semiconductor module. The semiconductor module may include, for example, a memory module including a module substrate 300 that corresponds to an external substrate, a first interposer substrate 100 on the module substrate 300, a second interposer substrate 400 mounted on the first interposer substrate 100, and a graphic processing unit 500 and a chip stack 600 that are mounted on the second interposer substrate 400.

The module substrate 300 may be provided. The module substrate 300 may include a printed circuit board (PCB) having a signal pattern on a top surface thereof.

Module terminals may be disposed below the module substrate 300. The module terminals may include solder balls or solder bumps, and based on type and arrangement of the module terminals, the semiconductor module may be provided in the form of one of a ball grid array (BGA) type, a fine ball-grid array (FBGA) type, and a land grid array (LGA) type. According to embodiments, the module terminals might not be provided.

The first interposer substrate 100 may be disposed on the module substrate 300. The first interposer substrate 100 may have a structure the same as or similar to that of the package substrate 100 discussed with reference to FIGS. 1 to 10. For example, the first interposer substrate 100 may include a core portion 110, a lower buildup portion 120, an upper buildup portion 130, and a buried material 140. The buried material 140 may bury the core portion 110 between the lower buildup portion 120 and the upper buildup portion 130, and the inner devices 150 may be inserted into a cavity CA formed in the core portion 110.

The first interposer substrate 100 may redistribute the second interposer substrate 400, which will be discussed below. The first interposer substrate 100 may be flip-chip mounted on the module substrate 300. For example, first external terminals 102 may be disposed on lower substrate pads 128 of the first interposer substrate 100, and the first external terminals 102 may be coupled to the module substrate 300.

The second interposer substrate 400 may be disposed on the first interposer substrate 100. The second interposer substrate 400 may include a second core portion 410 and a redistribution layer 420.

The second core portion 410 may extend in one direction. In a plan view, the second core portion 410 may include one core pattern. For example, the second core portion 410 may have a plate shape. The second core portion 410 may include a dielectric material. The second core portion 410 may include silicon (Si). For example, the second interposer substrate 400 may be a silicon-based interposer.

The second core portion 410 may include core vias 412 that each vertically penetrate the second core portion 410. The core vias 412 may extend from a bottom surface of the second core portion 410 toward a top surface of the second core portion 410. For example, the core vias 412 may be used for a vertical electrical connection in the second core portion 410. The core vias 412 may be exposed on the bottom and top surfaces of the second core portion 410. The core vias 412 may have bottom surfaces that are coplanar with the bottom surface of the second core portion 410. The core vias 412 may have top surfaces that are coplanar with the top surface of the second core portion 410. The core vias 412 may include a metal, such as copper (Cu) or tungsten (W).

The redistribution layer 420 may be disposed on the second core portion 410. The redistribution layer 420 may cover the top surface of the second core portion 410. The redistribution layer 420 may include one or more third substrate wiring layers that are sequentially stacked on the top surface of the second core portion 410. For example, the redistribution layer 420 may include two “third substrate” wiring layers. Each of the third substrate wiring layers may include a redistribution dielectric pattern 422 and a redistribution pattern 424 in the redistribution dielectric pattern 422. The redistribution pattern 424 of a certain third substrate wiring layer may be electrically connected to the redistribution pattern 424 of another third substrate wiring layer adjacent to the certain third substrate wiring layer.

The redistribution dielectric pattern 422 may include a dielectric polymer or a photo-imageable dielectric (PID). Alternatively, the redistribution dielectric pattern 422 may include a prepreg, an ajinomoto buildup film (ABF), a flame retardant 4 (FR-4), or bismaleimide triazine (BT).

The redistribution pattern 424 may include a circuit pattern. The redistribution pattern 424 may be disposed on the redistribution dielectric pattern 422. The redistribution pattern 424 may be disposed on a top surface of the redistribution dielectric pattern 422. The redistribution pattern 424 may protrude onto the top surface of the redistribution dielectric pattern 422. The redistribution pattern 424 may extend horizontally on the top surface of the redistribution dielectric pattern 422. On the redistribution dielectric pattern 422, the redistribution pattern 424 may be covered with another redistribution dielectric pattern 422. The redistribution pattern 424 may be a pad or line part of the third substrate wiring layer. The redistribution pattern 424 may include an electrically conductive material. For example, the redistribution pattern 424 may include copper (Cu), aluminum (Al), silver (Ag), tin (Sn), gold (Au), nickel (Ni), lead (Pb), titanium (Ti), and any combination thereof.

The redistribution pattern 424 may have a damascene structure. For example, the redistribution pattern 424 may have a via that protrudes onto a bottom surface thereof. The via may be a component for vertical connection between the redistribution patterns 424 of neighboring third substrate wiring layers. For example, the via may extend from the bottom surface of the upper wiring pattern 134 through the redistribution pattern 424 and may be coupled to a top surface of the redistribution pattern 424 in underlying another third substrate wiring layer. An upper portion of the redistribution pattern 424 positioned on the redistribution dielectric pattern 422 may be a head part used as a horizontal wiring line or pad, and the via of the redistribution pattern 424 may be a tail part. The redistribution pattern 424 may have a T shape.

The redistribution pattern 424 may be electrically connected to the core vias 412. The redistribution pattern 424 of a lowermost third substrate wiring layer in the redistribution layer 420 may penetrate the redistribution dielectric pattern 422 and may be coupled to the core vias 412.

Redistribution pads 426 may be disposed on the top surface of the redistribution dielectric pattern 422 of an uppermost third substrate wiring layer. The redistribution pads 426 may vertically penetrate the redistribution dielectric pattern 422 and may be coupled to the redistribution pattern 424 of the uppermost third substrate wiring layer. Alternatively, the redistribution pads 426 may be a portion of the redistribution pattern 424 exposed on the top surface of the redistribution dielectric pattern 422.

The second interposer substrate 400 may redistribute the graphic processing unit 500 and the chip stack 600. The second interposer substrate 400 may be flip-chip mounted on the first interposer substrate 100. For example, second external terminals 402 may be disposed on the bottom surfaces of the core vias 412 of the second interposer substrate 400, and the second external terminals 402 may be coupled to the upper substrate pads 138 of the first interposer substrate 100.

The graphic processing unit 500 may be disposed on the second interposer substrate 400. The graphic processing unit 500 may include a logic circuit. For example, the graphic processing unit 500 may be a logic chip. The graphic processing unit 500 may have a second circuit layer 502 disposed on a bottom surface of the graphic processing unit 500. The second circuit layer 502 may be electrically connected to the logic circuit. First bumps 506 may be disposed on a bottom surface of the graphic processing unit 500 or a bottom surface of the second circuit layer 502. The graphic processing unit 500 may be coupled through the first bumps 506 to the redistribution pads 426 of the second interposer substrate 400. A first underfill layer 508 may be disposed between the second interposer substrate 400 and the graphic processing unit 500. The first underfill layer 508 may at least partially surround the first bumps 506, while filling a space between the second interposer substrate 400 and the graphic processing unit 500.

The chip stack 600 may be disposed on the second interposer substrate 400. The chip stack 600 may be spaced apart from the graphic processing unit 500. The graphic processing unit 500 may have a thickness that is greater than those of semiconductor chips 610 and 620 of the chip stack 600. A top surface of the chip stack 600 may be located at a level that is the same as or higher than that of a top surface of the graphic processing unit 500.

The chip stack 600 may include a base substrate, second semiconductor chips 620 stacked on the base substrate, and a molding layer 630 that at least partially surrounds the second semiconductor chips 620. The following will describe in detail a configuration of the chip stack 600.

The base substrate may be a base semiconductor chip 610. For example, the base substrate may be a wafer-level semiconductor substrate formed of a semiconductor material such as silicon (Si). In this description below, the base semiconductor chip 610 and the base substrate may indicate the same component and may be allocated with the same reference numeral.

The base semiconductor chip 610 may include a base circuit layer 612 and base through electrodes 614. The base circuit layer 612 may be disposed on a bottom surface of the base semiconductor chip 610. The base circuit layer 612 may include an integrated circuit. For example, the base circuit layer 612 may be a memory circuit. The base semiconductor chip 610 may be a memory chip, such as a dynamic random access memory (DRAM), a static random access memory (SRAM), a magnetic random access memory (MRAM), or a flash memory. Alternatively, the base semiconductor chip 610 may be a logic chip. The base through electrodes 614 may penetrate the base semiconductor chip 610 in a direction perpendicular to the top surface of the second interposer substrate 400. The base through electrodes 614 may be electrically connected to the base circuit layer 612. The bottom surface of the base semiconductor chip 610 may be an active surface. According to embodiments, the base substrate may be a wiring substrate that does not include the base semiconductor chip 610.

The base semiconductor chip 610 may further include a protection layer. The protection layer may be disposed on the bottom surface of the base semiconductor chip 610, thereby covering the base circuit layer 612. The protection layer may include silicon nitride (SiN).

The second semiconductor chip 620 may be mounted on the base semiconductor chip 610. For example, the second semiconductor chip 620 and the base semiconductor chip 610 may constitute a chip-on-wafer (COW) structure. The second semiconductor chip 620 may have a width that is less than that of the base semiconductor chip 610.

The second semiconductor chip 620 may include a third circuit layer 622 and chip through electrodes 624. The third circuit layer 622 may include a memory circuit. For example, the second semiconductor chip 620 may be a memory chip, such as a dynamic random access memory (DRAM), a static random access memory (SRAM), a magnetic random access memory (MRAM), or a Flash memory. The third circuit layer 622 may include the same circuit as that of the base circuit layer 612, but the present inventive concepts are not necessarily limited thereto. The chip through electrodes 624 may penetrate the second semiconductor chip 620 in a direction perpendicular to the top surface of the second interposer substrate 400. The chip through electrodes 624 may be electrically connected to the third circuit layer 622. A bottom surface of the second semiconductor chip 620 may be an active surface.

The second semiconductor chip 620 may be bonded to the base semiconductor chip 610. For example, pads of the third circuit layer 622 of the second semiconductor chip 620 may be in contact with top surfaces of the base through electrodes 614 exposed on a top surface of the base semiconductor chip 610. Alternatively, the second semiconductor chip 620 may be mounted on the top surfaces of the base through electrodes 614 through terminals disposed on the pads of the third circuit layer 622.

The second semiconductor chip 620 may be provided in plural. For example, a plurality of second semiconductor chips 620 may be stacked on the base semiconductor chip 610. The number of stacked second semiconductor chips 620 may be about 8 to 32. An uppermost second semiconductor chip 620 might not include the chip through electrodes 624. In addition, the uppermost second semiconductor chip 620 may have a thickness that is greater than those of underlying other second semiconductor chips 620.

Neighboring second semiconductor chips 620 may be bonded to each other. For example, the pads of the third circuit layer 622 of each of the second semiconductor chips 620 may be in contact with top surfaces of the chip through electrodes 624 exposed on a top surface of an underlying second semiconductor chip 620. Alternatively, the second semiconductor chips 620 may be mounted on the top surfaces of the chip through electrodes 624 through terminals disposed on the pads of the third circuit layer 622.

The molding layer 630 may be disposed on the top surface of the bases semiconductor chip 610. The molding layer 630 may cover the base semiconductor chip 610 and at least partially surround the second semiconductor chips 620. A top surface of the molding layer 630 may be coplanar with that of the uppermost second semiconductor chip 620, and the uppermost second semiconductor chip 620 may be exposed from the molding layer 630. The molding layer 630 may include a dielectric polymer material. For example, the molding layer 630 may include an epoxy molding compound (EMC).

The chip stack 600 may be provided as discussed above.

Second bumps 606 may be disposed on the bottom surface of the chip stack 600, or a bottom surface of the base circuit layer 612. The chip stack 600 may be coupled through the second bumps 606 to the redistribution pads 426 of the second interposer substrate 400. A second underfill layer 608 may be disposed between the second interposer substrate 400 and the chip stack 600. The second underfill layer 608 may at least partially surround the second bumps 606, while filling a space between the second interposer substrate 400 and the chip stack 600.

An outer molding layer may be disposed on the second interposer substrate 400. The outer molding layer may cover the top surface of the second interposer substrate 400. The outer molding layer 800 may at least partially surround the graphic processing unit 500 and the chip stack 600. A top surface of the outer molding layer may be located at a level the same as that of the top surface of the chip stack 600. The outer molding layer may include a dielectric material. For example, the outer molding layer may include an epoxy molding compound (EMC).

According to embodiments, the second interposer substrate 400 formed of silicon (Si) may have high integration. The first interposer substrate 100 formed of glass may have high stiffness, and may have manufacturing costs that are less than that of the second interposer substrate 400. The semiconductor package may be configured such that the silicon-based second interposer substrate 400 and the glass-based first interposer substrate 100 are all provided as an interposer for redistribution of the graphic processing unit 500 and the chip stack 600. For example, as the second interposer substrate 400 is disposed adjacent to the graphic processing unit 500 and the chip stack 600, it may be easy to redistribute highly integrated wiring lines of the graphic processing unit 500 and the chip stack 600. In addition, the first interposer substrate 100 may be disposed below the second interposer substrate 400, and thus the semiconductor package may have superior electrical properties, may increase in structural stability, and may decrease in manufacturing cost.

Moreover, as the inner devices 150 are embedded in the core portion 110 of the first interposer substrate 100, the semiconductor package might not separately need a planar region for mounting a passive device. For example, the semiconductor package may become small in size and may have a planar area.

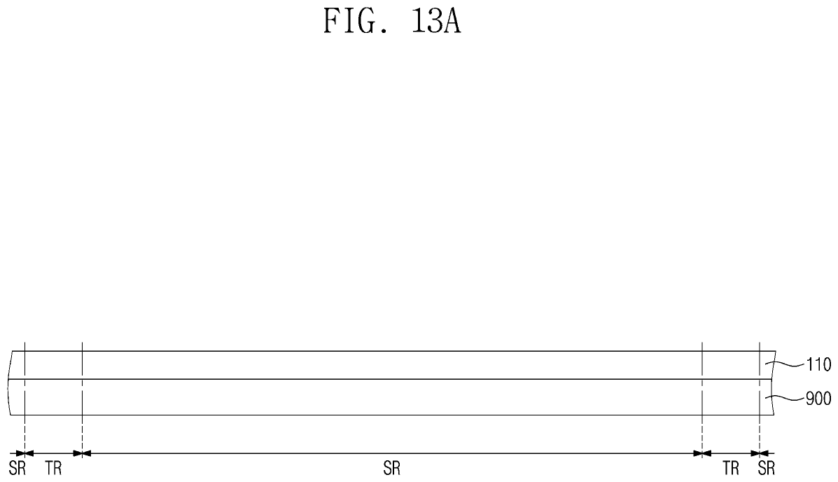

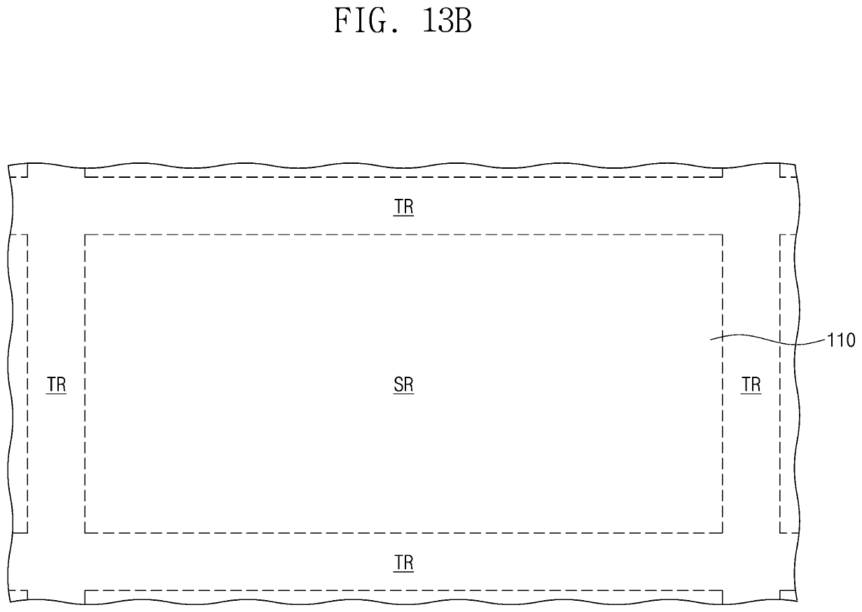

FIGS. 13A to 19A are cross-sectional views of a method of fabricating a semiconductor package according to embodiments of the present inventive concepts. FIGS. 13B to 19B are plan views of a method of fabricating a semiconductor package according to embodiments of the present inventive concepts.

Referring to FIGS. 13A and 13B, a first carrier substrate 900 may be provided. The first carrier substrate 900 may be a dielectric substrate including glass or polymer, or may be a conductive substrate including metal. An adhesive may be disposed on a top surface of the first carrier substrate 900. For example, the adhesive may include a glue tape.

A core portion 110 may be attached onto the first carrier substrate 900. The core portion 110 may have a plate shape. The core portion 110 may include a dielectric material. For example, the core portion 110 may include a glass fiber. In this case, a subsequently described package substrate 100 may be glass-based wiring substrate. The core portion 110 may have one or more substrate regions SR and a trench region TR. In a plan view, the trench region TR may have a tetragonal shape or a grid shape. The substrate regions SR may be positioned inside the trench region TR. For example, each of the substrate regions SR may be at least partially surrounded by the trench region TR. The substrate regions SR may be defined within the trench region TR. The substrate regions SR may be defined to indicate regions where the core portions 110 of package substrates are formed in a subsequent process. For example, the core portion 110 of one package substrate may be formed on one substrate region SR. The trench region TR may have a width of about 0.2 mm to about 10 mm. For example, an interval between neighboring substrate regions SR may range from about 0.2 mm to about 10 mm.

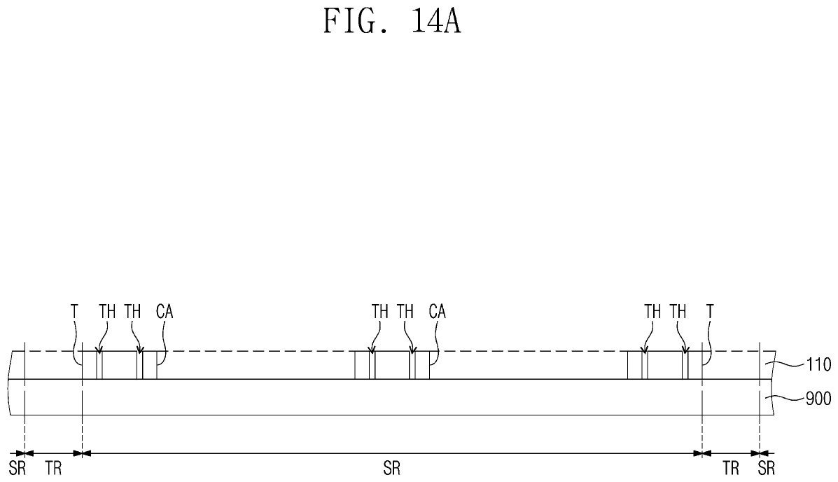

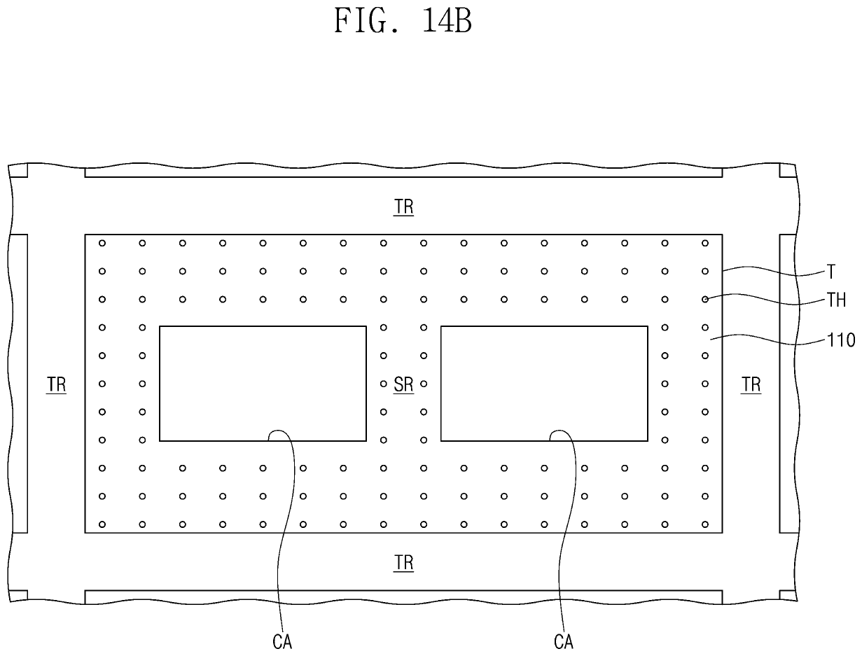

Referring to FIGS. 14A and 14B, cavities CA, via holes TH, and trenches T may be formed on the core portion 110. For example, the core portion 110 may undergo an etching process to form the cavities CA, the via holes TH, and the trenches T. A laser process may be used to form the cavities CA, the via holes TH, and the trenches T. The trenches T may be formed by performing an etching process on the trench region TR of the core portion 110. Thus, the core portion 110 may be divided into a plurality of individual core portions 110 that correspondingly remain on the substrate regions SR. The trenches T may be positioned between the core portions 110 on the first carrier substrate 900. On the substrate regions SR, the via holes TH and the trenches T may be formed on the core portions 110.

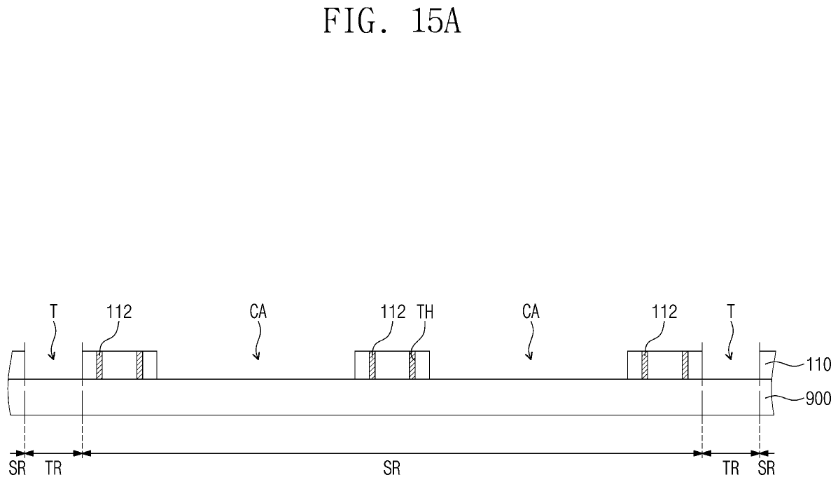

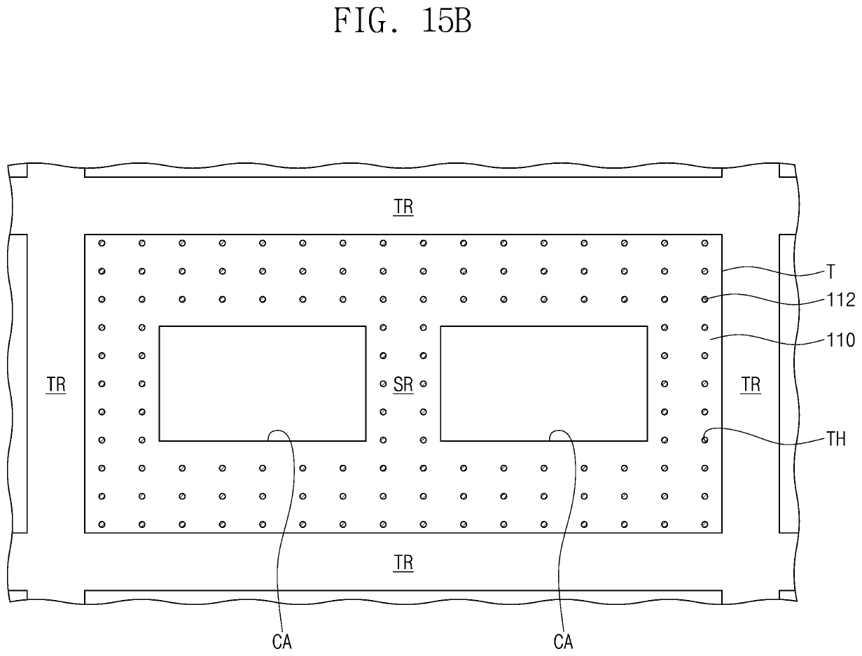

Referring to FIGS. 15A and 15B, the via holes TH may be filled with a conductive material to form vertical connection terminals 112. For example, a plating process may be performed to form the vertical connection terminals 112. The vertical connection terminals 112 may include a metal, such as copper (Cu) or tungsten (W).

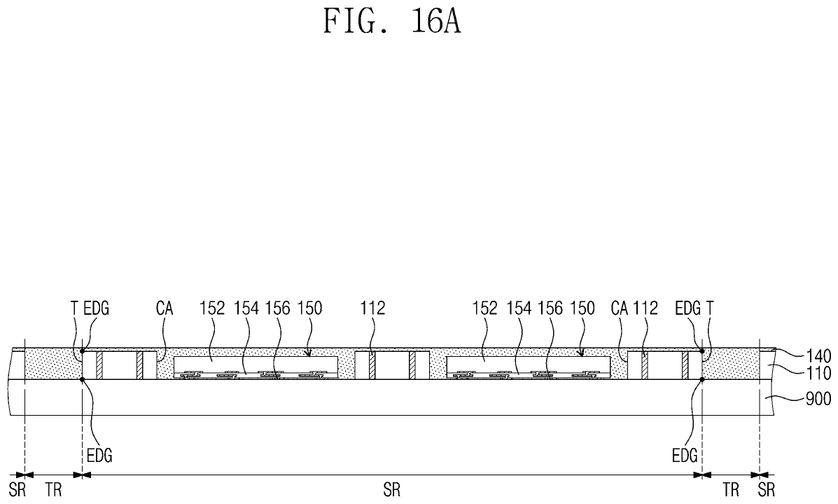

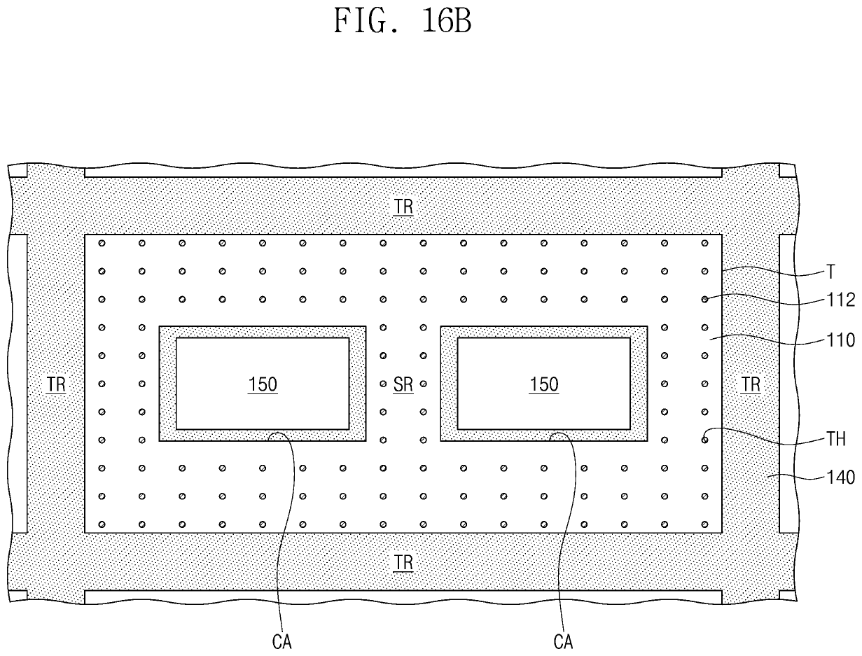

Referring to FIGS. 16A and 16B, inner devices 150 may be disposed on the first carrier substrate 900. The inner devices 150 may be correspondingly disposed in the cavities CA of the core portion 110. The inner devices 150 may be disposed such that chip pads 156 disposed in lower portions thereof may be directed toward the first carrier substrate 900. The inner devices 150 may have active surfaces on which the chip pads 156 are disposed, and the active surfaces of the inner devices 150 may be attached to the first carrier substrate 900.

A buried material 140 may be formed on the first carrier substrate 900. For example, a dielectric may be coated on the core portion 110 and the inner devices 150, and then the dielectric may be cured to form the buried material 140. The buried material 140 may cover a top surface of the core portion 110 and top surfaces of the inner devices 150. The dielectric may be introduced into a space between the core portion 110 and the inner devices 150, and the buried material 140 may fill a space between the core portion 110 and the inner devices 150. For example, the buried material 140 may fill unoccupied portions of the cavities CA in the core portion 110. The dielectric may be introduced into the trenches T, and the buried material 140 may fill the trenches T. Therefore, the buried material 140 may cover edges EDG of the core portion 110. The dielectric may include an ajinomoto buildup film (ABF). Alternatively, the dielectric may include a dielectric polymer such as an epoxy-based polymer or a polymer material such as a thermosetting resin.

Afterwards, the first carrier substrate 900 may be removed to expose a bottom surface of the buried material 140, a bottom surface of the core portion 110, and bottom surfaces of the inner devices 150. When an adhesive is present on the first carrier substrate 900, the adhesive may also be removed together with the first carrier substrate 900.

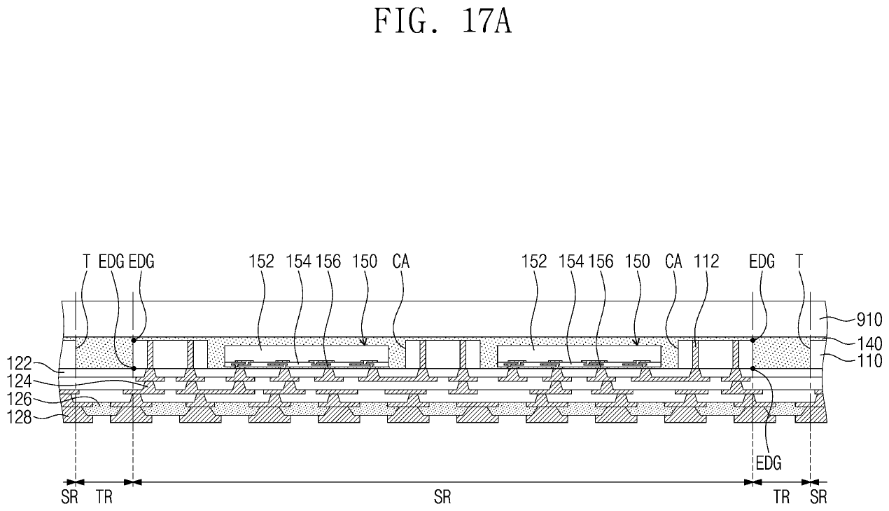

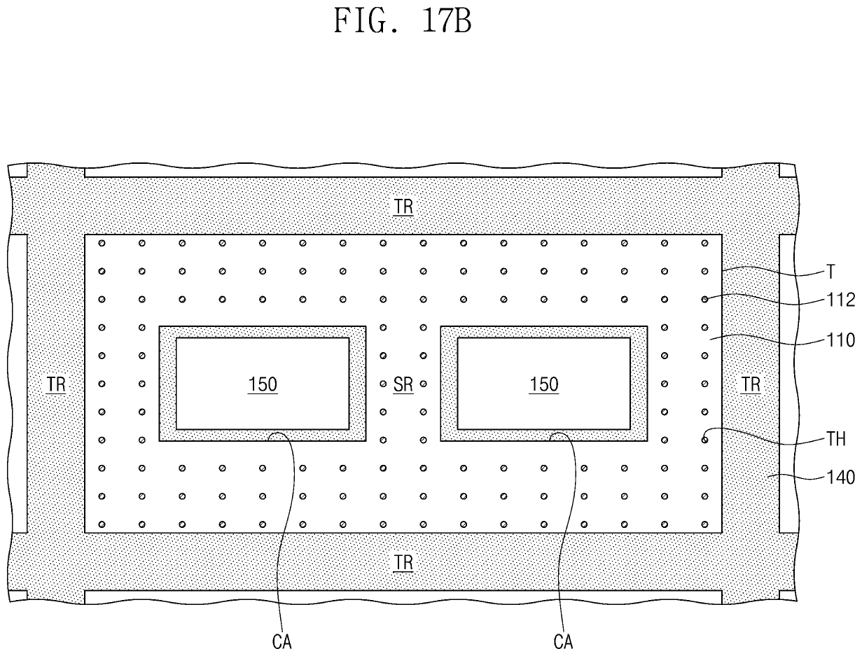

Referring to FIGS. 17A and 17B, a second carrier substrate 910 may be disposed on the buried material 140. The second carrier substrate 910 may be attached to a top surface of the buried material 140. For example, a glue tape or an adhesive may further be disposed on a bottom surface of the second carrier substrate 910.

A lower buildup portion 120 may be formed below the buried material 140, the core portion 110, and the inner devices 150. For example, a lower dielectric pattern 122 and a lower wiring pattern 124 may be formed on the bottom surface of the buried material 140, the bottom surface of the core portion 110, and the bottom surfaces of the inner devices 150, thereby forming one first substrate wiring layer of the lower buildup portion 120. For example, a dielectric layer may be formed on the bottom surface of the buried material 140, the bottom surface of the core portion 110, and the bottom surfaces of the inner devices 150, the dielectric layer may be patterned to form the lower dielectric pattern 122 that exposes the vertical connection terminals 112 of the core portion 110 and the chip pads 156 of the inner devices 150, a conductive layer may be formed on the lower dielectric pattern 122, and the conductive layer may be patterned to form the lower wiring pattern 124 electrically connected to the vertical connection terminals 112 and the chip pads 156. The formation of the first substrate wiring layer may be repeatedly performed to form the lower buildup portion 120.

Thereafter, the second carrier substrate 910 may be removed to expose the top surface of the buried material 140. When an adhesive is present on the second carrier substrate 910, the adhesive may also be removed together with the second carrier substrate 910.

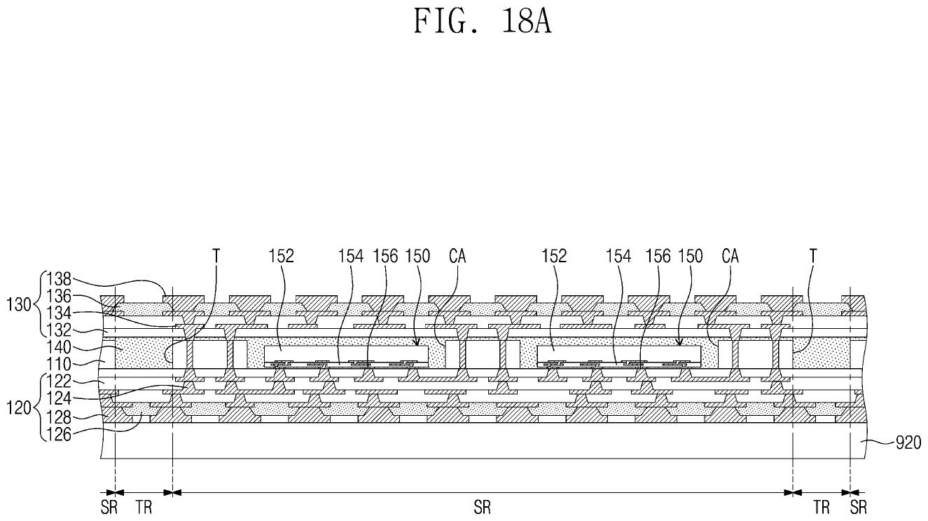

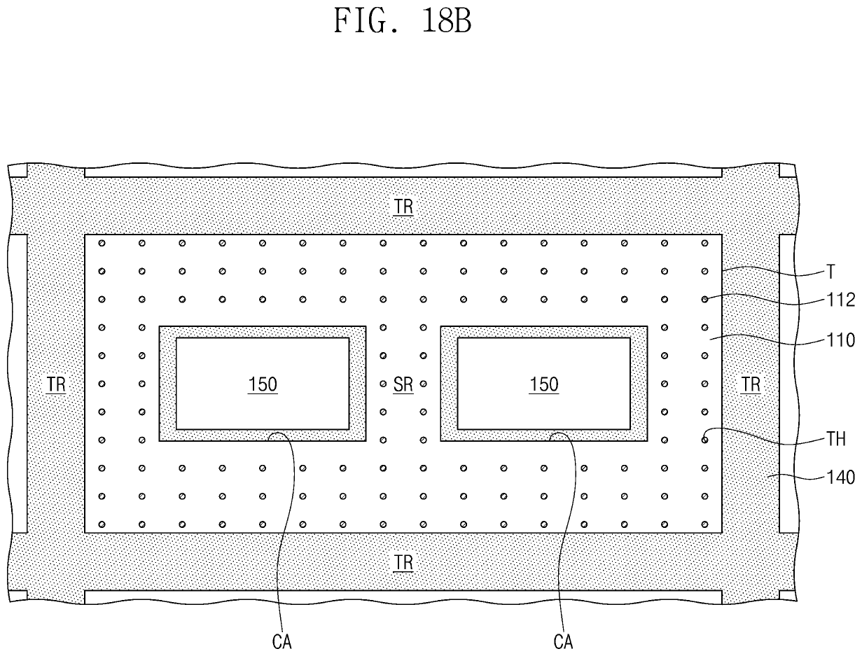

Referring to FIGS. 18A and 18B, a third carrier substrate 920 may be disposed below the lower buildup portion 120. The third carrier substrate 920 may be attached to a bottom surface of the lower buildup portion 120. For example, a glue tape or an adhesive may further be disposed on a top surface of the third carrier substrate 920.

An upper buildup portion 130 may be formed on the buried material 140. For example, an upper dielectric pattern 132 and an upper wiring pattern 134 may be formed on the top surface of the buried material 140, thereby forming one second substrate wiring layer of the upper buildup portion 130. For example, a dielectric layer may be formed on the top surface of the buried material 140, the dielectric layer and the buried material 140 may be patterned to form the upper dielectric pattern 132 that exposes the vertical connection terminals 112 of the core portion 110, a conductive layer may be formed on the upper dielectric pattern 132, and the conductive layer may be patterned to form the upper wiring pattern 134 electrically connected to the vertical connection terminals 112. The formation of the second substrate wiring layer may be repeatedly performed to from the upper buildup portion 130.

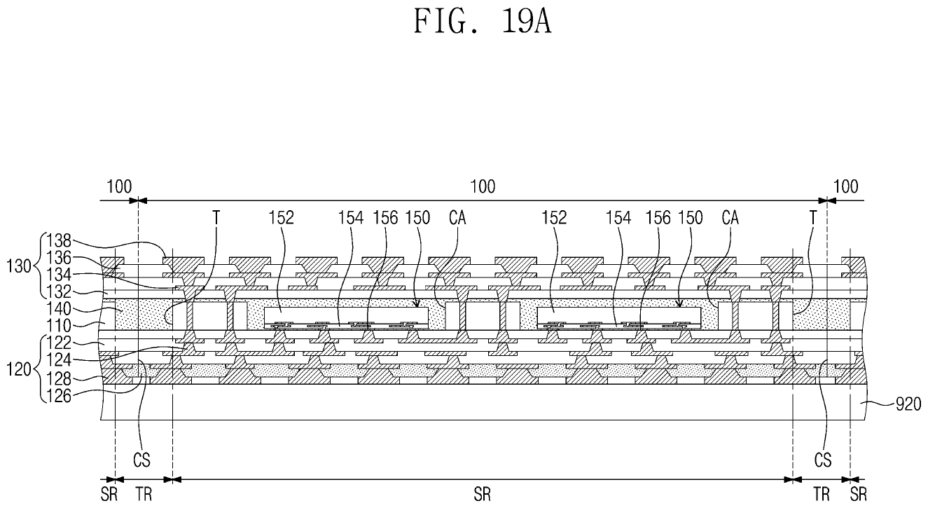

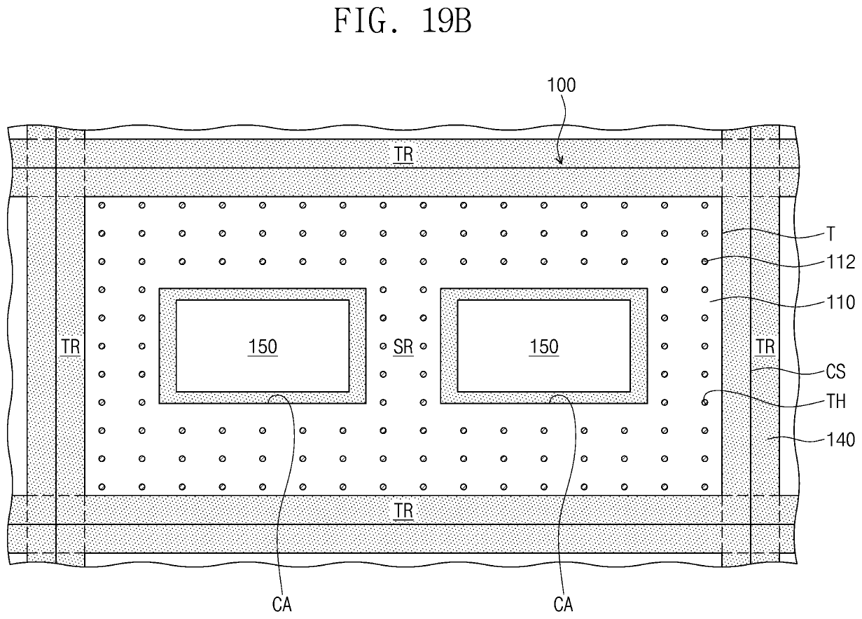

Referring to FIGS. 19A and 19B, the lower buildup portion 120, the buried material 140, and the upper buildup portion 130 may be cut to individually separate package substrates 100 from each other. For example, the lower buildup portion 120, the buried material 140, and the upper buildup portion 130 may undergo a singulation process performed along a sawing line. The sawing line may be positioned in the trench region TR, and in a plan view, may extend along the trench region TR. For example, the lower buildup portion 120, the buried material 140, and the upper buildup portion 130 may be sawed to separate a plurality of package substrates 100 from each other. The core portion 110 of each of the package substrates 100 might not be cut. For example, the core portions 110 may be horizontally spaced apart from each other from a cutting surface CS that appears through the singulation process. A distance between the cutting surface CS and the core portions 110 may range from about 0.1 mm to about 3 mm.

After that, the third carrier substrate 920 may be removed to expose the bottom surface of the lower buildup portion 120. When an adhesive is present on the third carrier substrate 920, the adhesive may also be removed together with the third carrier substrate 920.

Referring back to FIG. 1, external pads 102 may be attached onto lower substrate pads 128 of the lower buildup portion 120.

According to embodiments, like the embodiments of FIGS. 11 and 12, the package substrate 100 may be disposed thereon with various apparatuses or substrates such as the first semiconductor chip 200, the module substrate 300, the graphic processing unit 500, and/or the chip stack 600.

In a semiconductor package, according to embodiments of the present inventive concepts, a buried material may protect edges of a core portion against external impact and stress, and it may be possible to provide a package substrate whose structural stability is increased and a semiconductor package including the package substrate may also be provided.

In addition, a second interposer substrate formed of silicon (Si) may have high integration, and a first interposer substrate formed of glass may have high stiffness and manufacturing cost that is less than that of the second interposer substrate. For example, as the second interposer substrate is disposed adjacent to a graphic processing unit and a chip stack, it may be easy to redistribute highly integrated wiring lines of the graphic processing unit and the chip stack. The first interposer substrate may be disposed below the second interposer substrate, and thus the semiconductor package may have superior electrical properties, may increase in structural stability, and may decrease in manufacturing costs. Moreover, as inner devices are embedded in a core portion of the first interposer substrate, the semiconductor package might not separately need a planar region for mounting a passive device. For example, the semiconductor package may become small in size and may have a planar area.

Although the present inventive concepts have been described in connection with embodiments of the present inventive concepts illustrated in the accompanying drawings, it will be understood by one of ordinary skill in the art that variations in form and detail may be made therein without departing from the spirit and essential feature of the present inventive concepts.

1. A semiconductor package, comprising:
a wiring substrate; and
a first semiconductor chip disposed on the wiring substrate,
wherein the wiring substrate includes:
a first core portion including glass, wherein the first core portion includes a cavity that vertically penetrates the first core portion;
a plurality of first core vias that each vertically penetrate the first core portion;
a passive device disposed in the cavity of the first core portion;
a buried material disposed on the first core portion and the first core vias, wherein the buried material fills the cavity and covers a top surface and outer lateral surfaces of the first core portion; and
an upper buildup portion disposed on the buried material, and
wherein the upper buildup portion includes:
a first dielectric pattern; and
a first wiring pattern that penetrates the first dielectric pattern and the buried material and is coupled to the first core vias.

2. The semiconductor package of claim 1, wherein each of the first core vias includes:
an upper land contact disposed on the top surface of the first core portion;
a lower land contact disposed on a bottom surface of the first core portion; and
a via that vertically penetrates the first core portion to connect the upper land contact and the lower land contact to each other.

3. The semiconductor package of claim 1, further comprising a lower buildup portion disposed below the first core portion and the buried material,
wherein the lower buildup portion includes:
a second dielectric pattern; and
a second wiring pattern that penetrates the second dielectric pattern and is coupled to the first core vias.

4. The semiconductor package of claim 3, wherein
an active surface of the passive device is directed toward the lower buildup portion, and
the second wiring pattern penetrates the second dielectric pattern and is coupled to the passive device.

5. The semiconductor package of claim 3, wherein the first semiconductor chip is disposed on the upper buildup portion of the wiring substrate.

6. The semiconductor package of claim 1, wherein the buried material includes an ajinomoto buildup film (ABF) or an epoxy molding compound (EMC).

7. (canceled)

8. The semiconductor package of claim 1, wherein
an active surface of the passive device is directed toward the upper buildup portion, and
the first wiring pattern penetrates the first dielectric pattern and the buried material and is coupled to the passive device.

9. The semiconductor package of claim 1, wherein a bottom surface of the buried material is coplanar with a bottom surface of the first core portion.

10. The semiconductor package of claim 1, wherein a distance between the outer lateral surfaces of the first core portion and outer lateral surfaces of the buried material is in a range of about 0.1 mm to about 3 mm.

11. The semiconductor package of claim 1, further comprising a chip stack disposed on the wiring substrate,
wherein the chip stack includes a plurality of second semiconductor chips that are vertically stacked on the wiring substrate.

12. The semiconductor package of claim 11, further comprising:
an interposer substrate disposed between the first semiconductor chip and the wiring substrate and between the chip stack and the wiring substrate; and
a module substrate on which the wiring substrate is disposed,
wherein the interposer substrate is disposed on the upper buildup portion of the wiring substrate,
wherein the interposer substrate includes:
a second core portion;
a second core via that vertically penetrates the second core portion; and
a redistribution layer disposed on a top surface of the second core portion and is electrically connected to the second core via, and
wherein the first semiconductor chip and the chip stack are each disposed on the redistribution layer.

13. (canceled)

14. A semiconductor package, comprising:
a first interposer substrate;
a second interposer substrate disposed on the first interposer substrate;
a first semiconductor chip disposed on the second interposer substrate;
a chip stack disposed on the second interposer substrate and spaced apart from the first semiconductor chip, the chip stack including a plurality of second semiconductor chips that are vertically stacked; and
a plurality of connection terminals disposed below the first interposer substrate,
wherein the first interposer substrate includes:
a lower buildup portion;
a first core portion disposed on the lower buildup portion and including glass, wherein the first core portion includes a cavity that vertically penetrates the first core portion;
a buried material disposed on the lower buildup portion and covering the first core portion;
an upper buildup portion disposed on the buried material; and
a passive device disposed in the cavity of the first core portion,
wherein outer lateral surfaces of the first core portion are disposed more inwardly than outer lateral surfaces of the buried material,
wherein the second interposer substrate includes a second core portion, and
wherein the second core portion includes a material that is different from a material of the first core portion.

15. The semiconductor package of claim 14, wherein the buried material fills the cavity and covers a top surface and the outer lateral surfaces of the first core portion.

16. The semiconductor package of claim 14, wherein the upper buildup portion includes:
a first dielectric pattern; and
a first wiring pattern that penetrates the first dielectric pattern and the buried material and is coupled to the first core portion.

17. The semiconductor package of claim 16, wherein
an active surface of the passive device is directed toward the upper buildup portion, and
the first wiring pattern penetrates the first dielectric pattern and the buried material and is coupled to the passive device.

18. (canceled)

19. The semiconductor package of claim 14, wherein the first interposer substrate further includes a plurality of first core vias that each vertically penetrate the first core portion,
wherein each of the first core vias includes:
an upper land contact disposed on a top surface of the first core portion;
a lower land contact disposed on a bottom surface of the first core portion; and
a via that vertically penetrates the first core portion and connects the upper land contact and the lower land contact to each other.

20. The semiconductor package of claim 14, wherein the lower buildup portion includes:
a second dielectric pattern; and
a second wiring pattern that penetrates the second dielectric pattern and is coupled to the first core portion.

21-22. (canceled)

23. The semiconductor package of claim 14, wherein
the first core portion is in contact with the lower buildup portion, and
a bottom surface of the buried material is coplanar with a bottom surface of the first core portion.

24-26. (canceled)

27. A semiconductor package, comprising:
a wiring substrate; and
a first semiconductor chip disposed on the wiring substrate,
wherein the wiring substrate includes:
a lower buildup portion;
an upper buildup portion disposed on the lower buildup portion;
a buried material that fills a space between the lower buildup portion and the upper buildup portion;
a first core portion in the buried material, wherein the first core portion includes a cavity that penetrates the first core portion, and wherein a distance between outer lateral surfaces of the first core portion and outer lateral surfaces of the buried material is in a range of about 0.1 mm to about 3 mm;
a plurality of first core vias that each vertically penetrate the first core portion; and
a passive device disposed in the cavity of the first core portion,
wherein the upper buildup portion includes:
a first dielectric pattern; and
a first wiring pattern that penetrates the first dielectric pattern and the buried material and is coupled to the first core vias,
wherein the lower buildup portion includes:
a second dielectric pattern; and
a second wiring pattern that penetrates the second dielectric pattern and is coupled to the first core vias, and
wherein a stiffness of a first material included in the first core portion is greater than each of a stiffness of a second material included in the first dielectric pattern and a stiffness of a third material included in the second dielectric pattern.

28-36. (canceled)

37. The semiconductor package of claim 27, further comprising a chip stack disposed on the wiring substrate,
wherein the chip stack includes a plurality of second semiconductor chips that are vertically stacked on the wiring substrate,
wherein the semiconductor package further comprises an interposer substrate disposed between the first semiconductor chip and the wiring substrate and disposed between the chip stack and the wiring substrate,
wherein the interposer substrate is disposed on the upper buildup portion of the wiring substrate,
wherein the interposer substrate includes:
a second core portion;
a second core via that vertically penetrates the second core portion; and
a redistribution layer disposed on a top surface of the second core portion and electrically connected to the second core via, and
wherein the first semiconductor chip and the chip stack are disposed on the redistribution layer, and
wherein the second core portion includes silicon (Si).

38-43. (canceled)
